(19) United States
(12) Patent Application Publication
(10) Pub. No.: US 2019/0120144 A1
(43) Pub. Date: Apr. 25, 2019

(54) SPARK GAP CIRCUIT

(71) Applicant: Unison Industries, LLC, Jacksonville, FL (US)

(72) Inventor: Charles Marshall Cook, Jacksonville, FL (US)

(21) Appl. No.: 15/790,662

(22) Filed: Oct. 23, 2017

(51) Int. Cl. F02C 7/266; F02P 3/08; F02P 15/00; H03K 3/57

(52) U.S. Cl. CPC F02C 7/266; H03K 3/57; F02P 15/003; F02P 3/0807

(57) ABSTRACT

An apparatus and a method for a circuit can include a voltage divider having a first and a second impedance in series, and having a voltage divider output. A switchable element is arranged in parallel with the first impedance and connected with the voltage divider output. The switchable element has an open state and a closed state. A spark gap device is configured to not generate a spark when the switchable element is in the open state and generate a spark when the switchable element is in the closed state.

### BACKGROUND OF THE INVENTION

In spark ignition systems, a spark gap device is often used to electrically couple a power source to an igniter. During operations, the spark gap device generates a spark across terminals separated by a dielectric, such that a large amount of power is conducting across the spark gap device, and provided to the igniter to, for example, ignite a combustible fuel. The breakdown gap voltage can be determined based upon the environment within the spark gap system as the threshold voltage required to spark across the dielectric gap. A stable breakdown gap voltage is key to ignition system operation. The breakdown gap voltage is determined by electrode geometry, electrode surface material, electrode gap distance and the gas mixture in the electrode gap. In typical spark gaps, a trace amount of radioactive Krypton-85 (Kr85) gas, or another radioactive gas, is added to the gas mixture present in the electrode gap. Addition of Kr85 or other radioactive gases can generally result in more stable or more predictable breakdown gap voltages. This disclosure describes a method for stabilizing gap breakdown without introducing radioactive gas.

### BRIEF DESCRIPTION OF THE INVENTION

In one aspect, the disclosure relates to a circuit including a circuit including a voltage divider having a first impedance and a second impedance in series, with a voltage divider output between the first and second impedances, a switchable element arranged electrically in parallel with the first impedance and connected with the voltage divider output, and having an open state enabling a first current path through the first impedance and a closed state enabling a second current path bypassing the first impedance, and a spark gap device arranged electrically in parallel with at least a portion of the voltage divider and defining a breakdown voltage whereby the spark gap device generates a spark in response to application of voltage greater than the breakdown voltage. The first impedance and the second impedance are selected such that, in response to the circuit receiving a voltage supply greater than the breakdown voltage, the spark gap device does not generate the spark when the switchable element is in the open state and the spark gap device generates the spark when the switchable element is in the closed state and bypasses the first impedance.

In another aspect, the disclosure relates to a method of providing a spark gap circuit, the method including connecting a first impedance and a second impedance in series for a voltage divider, arranging a voltage divider output between the first and second impedance, arranging a switchable element electrically in parallel with the first impedance and connected with the voltage divider output, arranging a spark gap device defining a breakdown voltage electrically in parallel with at least a portion of the voltage divider, and selecting values for the first impedance and the second impedance such that, in response to the circuit receiving a predetermined voltage supply greater than the breakdown voltage, the spark gap device does not generate a spark when the switchable element is in an open state and the spark gap device generates a spark when the switchable element is in a closed state.

### BRIEF DESCRIPTION OF THE DRAWINGS

In the drawings:

FIG. 1 is a schematic view of an igniter system for an engine including a spark gap circuit system, in accordance with various aspects described herein.

FIG. 2 is a schematic view of the spark gap circuit system of FIG. 1 illustrating an exemplary electrical circuit, in accordance with various aspects as described herein.

FIG. 3 is a schematic of the spark gap circuit system of FIG. 2 illustrating the generation of a spark across the spark gap device, in accordance with various aspects as described herein.

FIG. 4 is a plot graph illustrating an operation of the spark gap circuit system of FIGS. 2 and 3 in response to an application of voltage over time, in accordance with various aspects described herein.

FIG. 5 is a schematic view of another exemplary spark gap circuit system having a three-terminal system, in accordance with various aspects as described herein.

FIG. 6 is a schematic view of the spark gap circuit system of FIG. 5 illustrating a series of diagrams describing the generation of a spark across the spark gap device, in accordance with various aspects described herein.

FIG. 7 is a flow chart illustrating a method of providing a spark gap circuit, in accordance with various aspects as described herein.

### DESCRIPTION OF EMBODIMENTS OF THE INVENTION

Aspects of the disclosure described herein are directed to a circuit system having a solid state electronic switch arranged with a non-radioactive spark gap device. The system provides for a fast switching speed and robust power handling of the spark gap device, combined with the precision switching voltage of the electronic switch, without utilizing a radioactive element included with the spark gap device. For purposes of illustration, the present disclosure is described with respect to an igniter system for a turbine engine. It should be understood, however, that aspects of the disclosure described herein are not so limited and may have general applicability within any engine or suitable electrical system utilizing a spark gap.

All directional references (e.g., radial, axial, proximal, distal, upper, lower, upward, downward, left, right, lateral, front, back, top, bottom, above, below, vertical, horizontal, clockwise, counterclockwise, upstream, downstream, forward, aft, etc.) are only used for identification purposes to aid the reader's understanding of the present disclosure, and do not create limitations, particularly as to the position, orientation, or use of aspects of the disclosure described herein. Connection references (e.g., attached, coupled, connected, and joined) are to be construed broadly and can include intermediate members between a collection of elements and relative movement between elements unless otherwise indicated. As such, connection references do not necessarily infer that two elements are directly connected and in fixed relation to one another. The exemplary drawings are for purposes of illustration only and the dimensions, positions, order and relative sizes reflected in the drawings attached hereto can vary.

Additionally, while terms such as “voltage”, “current”, and “power” can be used herein, it will be evident to one skilled in the art that these terms can be interchangeable when describing aspects of the electrical circuit, or circuit operations. In non-limiting examples, connections or disconnections can be selectively configured to provide, enable, disable, or the like, an electrical connection between respective elements. Non-limiting example power distribution bus connections or disconnections can be enabled or operated by way of switching, bus tie logic, or any other connectors configured to enable or disable the energizing of electrical components.

Also as used herein, while sensors can be described as “sensing” or “measuring” a respective value, sensing or measuring can include determining a value indicative of or related to the respective value, rather than directly sensing or measuring the value itself. The sensed or measured values can further be provided to additional components. For instance, the value can be provided to a controller module or processor, and the controller module or processor can perform processing on the value to determine a representative value or an electrical characteristic representative of said value.

As used herein, a “system” or a “controller module” can include at least one processor and memory. Non-limiting examples of the memory can include Random Access Memory (RAM), Read-Only Memory (ROM), flash memory, or one or more different types of portable electronic memory, such as discs, DVDs, CD-ROMs, etc., or any suitable combination of these types of memory. The processor can be configured to run any suitable programs or executable instructions designed to carry out various methods, functionality, processing tasks, calculations, or the like, to enable or achieve the technical operations or operations described herein. The program can include a computer program product that can include machine-readable media for carrying or having machine-executable instructions or data structures stored thereon. Such machine-readable media can be any available media, which can be accessed by a general purpose or special purpose computer or other machine with a processor. Generally, such a computer program can include routines, programs, objects, components, data structures, algorithms, etc., that have the technical effect of performing particular tasks or implement particular abstract data types.

As used herein, a controllable switching element, or a “switch” is an electrical device that can be controllable to toggle between a first mode of operation, wherein the switch is “closed” intending to transmit current from a switch input to a switch output, and a second mode of operation, wherein the switch is “open” intending to prevent current from transmitting between the switch input and switch output. In non-limiting examples, connections or disconnections, such as connections enabled or disabled by the controllable switching element, can be selectively configured to provide, enable, disable, or the like, an electrical connection between respective elements.

Aspects of the disclosure can be implemented in any electrical circuit environment having a switch. A non-limiting example of an electrical circuit environment that can include aspects of the disclosure can include an aircraft power system architecture, which enables production or conduction of electrical power from a power source to a destination via at least one solid state switch, such as a solid state power controller (SSPC) switching device. One non-limiting example of the SSPC can include a silicon (Si), silicon carbide (SiC) or Gallium Nitride (GaN) based, high power switch. Si, SiC or GaN can be selected based on their solid state material construction, their ability to handle high voltages and large power levels in smaller and lighter form factors, and their high speed switching ability to perform electrical operations very quickly. Additional switching devices or additional silicon-based power switches can be included.

The exemplary drawings are for purposes of illustration only and the dimensions, positions, order and relative sizes reflected in the drawings attached hereto can vary.

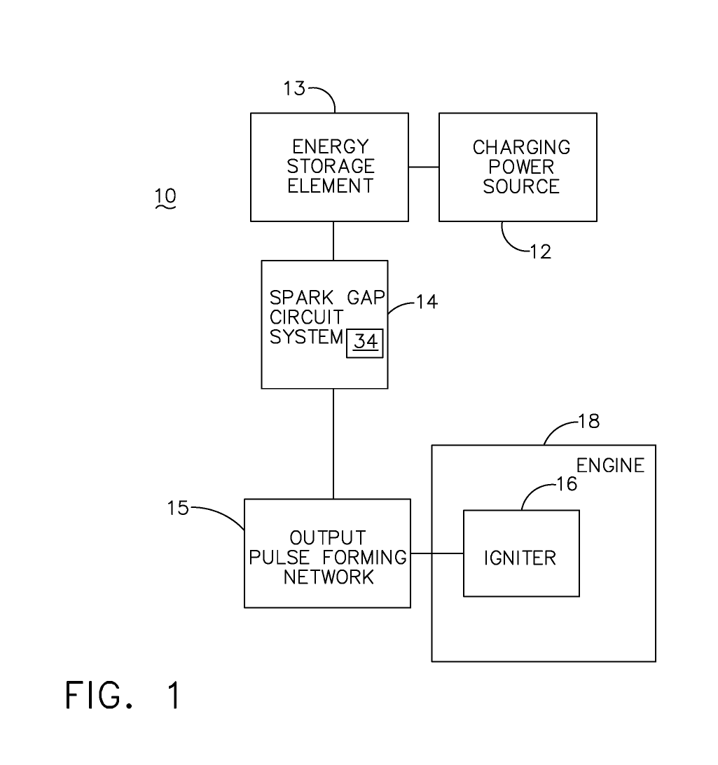

Referring now to FIG. 1, a spark ignition system 10 can include a charging power source 12, an energy storage element 13, a spark gap circuit system 14, an output pulse forming network 15, and an igniter 16, housed inside an engine 18, as a power output. The charging power source 12 can in a power source, such as a set of batteries, a generator output, or the like, a high voltage capacitor, or a combination thereof, and can be adapted, configured, or the like, to supply a high voltage to the energy storage element 13. The energy storage element 13 is further connected with the spark gap circuit system 14. In one non-limiting example, the charging power source 12 can supply a high voltage between 1-10 kilovolts (kV), however a wider voltage range is contemplated. The spark gap circuit system 14 can include and utilize a spark gap device 34 to operably allow or enable the supplying of the high voltage to the output pulse forming network 15. The output pulse forming network supplies a predetermined waveform to the igniter 16, for example, for igniting a combustible fuel within the engine 18, or for otherwise operating a downstream system via ignition. In one non-limiting example, the engine can be a turbine engine, with the igniter 16 housed inside of a combustor or combustion section.

In the spark gap ignition system 10, it is desirable to have a spark gap device 34 that is capable of operating under predictable conditions, characteristics, or a predictable range of conditions or characteristics. Predictable conditions, characteristics, or ranges thereof can include, but are not limited to: operating at a high impedance off-state (or non-conducting or non-spark) voltage (e.g. when voltage is below a predetermined breakdown voltage), low off-state leakage (for example, to avoid loading the power charging source 12), operating at a low impedance on-state (or conducting or sparking), the ability to switch from off-state to on-state (e.g. non-conducting to sparking) at a precise, predetermined breakdown, or predictable voltage (such as within a range of +/−2% of a predetermined or predictable voltage value or range), the ability to switch from off to on very quickly (e.g. off-state to on-state in less than 100 nanoseconds), very high peak forward currents (such as several thousand amperes), low on (e.g. conducting or sparking) state resistance to increase efficiency and reduce self-heating, the ability to self-reset (from on-state to off-state) after a discharge event, and the ability to operate over a wide temperature range (−55 degrees Celsius to 200 degrees Celsius or greater). Historically, these requirements were achieved utilizing spark gaps including mixture of gases including radioactive gas as a dielectric, such as Kr85. The spark gap circuit system 14 as described herein can achieve these operational conditions without a radioactive dielectric.

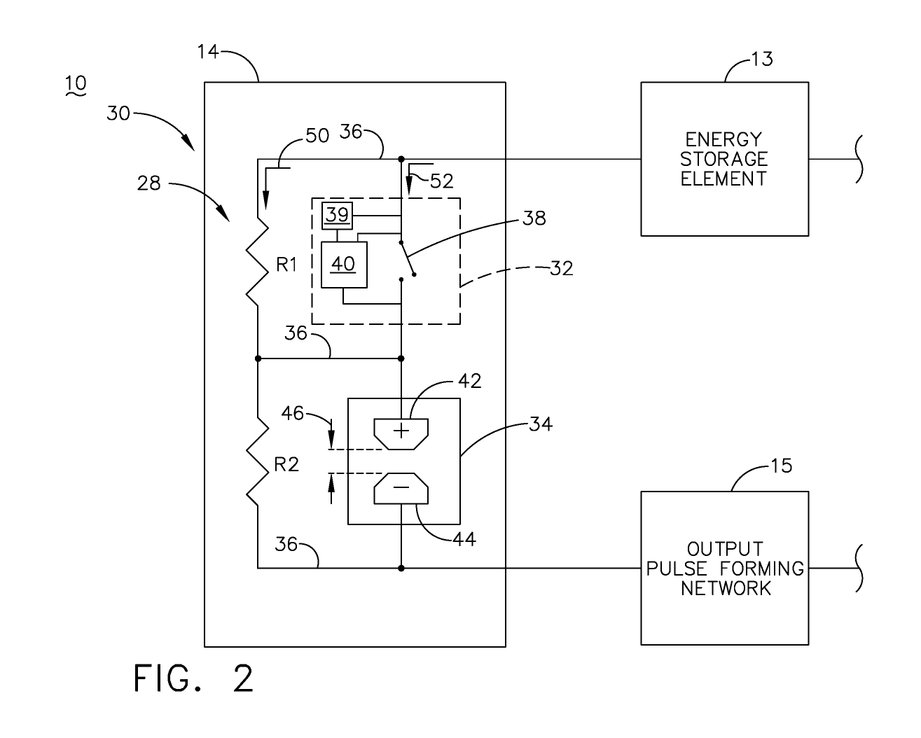

Referring now to FIG. 2, the spark gap circuit system 14 is illustrated in further detail, as an exemplary two-terminal circuit 30. The two terminal circuit 30 can be formed on a printed circuit board, for example. The two terminal circuit 30 is coupled to the energy storage element 13 at a first end, and is coupled to the output pulse shaping network 15, opposite of the energy storage element 13. One example of an energy storage element 13 is a capacitor. One example of an output pulse shaping network 15 can include a network of inductors, capacitors, or a combination thereof. Aspects of the disclosure can be included in spark gap ignition systems lacking an energy storage element 13, an output pulse shaping network 15, or a combination thereof. The two terminal circuit 30 can couple to the energy storage element 13 and the output pulse shaping network 15 by any suitable means, such as electrical conduits, electrical wiring, or electrical connectors, in non-limiting examples.

The two-terminal circuit 30 has electrical components including a first resistor R1 having a first impedance or resistance, a second resistor R2 having a second impedance or resistance, a switchable element shown as an exemplary solid state switch 32, and the spark gap device 34. The first resistor R1 is in series with the second resistor R2 defining a voltage divider 28 having a voltage divider output between the first and second impedances R1, R2. A system of electrical wires, traces, or other conductive conduits 36 can interconnect the electrical components. In one example, an electrical conduit 36 can form the voltage divider output between the first and second impedances R1, R2. As shown, the solid state switch 32 is arranged electrically in parallel with the first resistor R1 and the solid state switch 32 output is connected to the voltage divider output.

The solid state switch 32 includes can include a switchable element 38, a voltage sensor 39, and controller module 40. The switchable element 38 is shown in the open position defining an open state for the solid state switch 32. The voltage sensor 39 can sense, measure, or otherwise determine the voltage at the solid state switch 32 input. While the voltage sensor 39 is shown internal of the solid state switch 32, it should be appreciated that the voltage sensor 39 can be positioned anywhere suitable along the circuit to measure the voltage relative to the solid state switch 32, including but not limited to external of the solid state switch 32. The controller module 40 can be communicatively connected with the voltage sensor 39 and the switchable element 38. In this sense, the controller module 40 can provide, supply, generate, or the like, a control signal provided to the switchable element 38 to operate the switchable element 38, as needed. The controller module 40 can also receive the sensed or measured voltage, or a signal representative thereof, from the voltage sensor 39. Non-limiting examples of the controller module 40 can be configured such that controller module 40 operably instructs the switchable element 38 to open or close at a predetermined threshold voltage, as determined by the voltage sensor 39.

The spark gap device 34 includes two electrodes, shown as an anode 42 and a cathode 44, separated by a gap 46. The spark gap device 34 can be arranged in parallel with at least a portion of the voltage divider 28, such as with the second resistor R2, and can be connected with the voltage divider output at the anode 42 and connected with the output pulse forming network 15 at the cathode 44. The spark gap device 34 can includes a fluidly sealed housing containing the anode 42 and the cathode 44. The housing of the spark gap device 34 can include a gas or a mixture of gases within the housing. The gas or gases can be non-radioactive. In one example, the gap 46 can be 1.57 millimeters (mm) or 0.062 inches (in).

The spark gap device 34 can define a breakdown voltage, a breakdown voltage threshold, or a breakdown voltage threshold range, whereby, upon exposure the anode 42 and cathode 44 to a voltage difference equal to or greater than the spark gap device 34 breakdown voltage (V_{SGBR}), the spark gap device 34 generates a spark across the anode 42 and cathode 44. Thus, the voltage difference greater than or equal to the breakdown voltage is able to overcome the dielectric strength in the gap 46 between the anode 42 and cathode 44. The breakdown voltage at the gap distance 46, pressure, and elemental environment (such as gas held within the spark gap device 34) can be approximately 2.25 kV, in one non-limiting example. The breakdown voltage can be a range of voltages, such as 2.25 kV+/−250V, for example, while any range is contemplated. Thus, when a voltage greater than 2.50 kV is provided to the anode 42, a spark is generated from anode 42 to the cathode 44 to electrically couple the cathode 44 to the anode 42, and ultimately deliver current or power to the igniter, for ignition, as described herein.

However, such a breakdown voltage can a have a standard deviation of error that is greater than +/−250V when measured among differing sparks between the anode 42 and the cathode 44, and is outside of engine operational requirements. It should be appreciated that the elemental environment, pressures, gap distance, and breakdown voltage are exemplary to facilitate understanding, and should not be understood as limiting of the spark gap device 34. It should be further understood that variation among the chemical composition within the spark gap device 34, the pressure, and the gap distance can be used to vary the breakdown voltage, and can be further adapted to tailor the breakdown voltage to a desired range, as well as increasing or decreasing the error around the breakdown voltage. For example, increasing the distance of the gap 46 or dielectric gas pressure can increase the breakdown voltage.

The spark gap circuit system 14 can include two primary current paths during conducting operations, denoted by the status or state of the switchable element 38. When the switchable element 38 is open, a first current path (illustrated as arrow 50) is enabled, wherein current traverses the first impedance at the first resistor R1, followed by the second impedance at the second resistor R2. The first current path 50 assumes the voltage at the voltage divider output is less than the breakdown voltage of the spark gap device 34. When the switchable element 38 is closed, a second current path 52 is enabled, bypassing the first resistor R1, wherein current traverses the solid state switch 32, to the voltage divider output. In instances wherein the voltage at the voltage divider output is equal to or greater than the breakdown voltage of the spark gap device 34, the spark gap device can operate to generate a spark.

Non-limiting aspects of the disclosure can include selecting, determining, or configuring the first and second resistors R1, R2 to selectably operate the spark gap circuit system 14 to operably or reliably control the generation of a spark in the spark gap device 34, by way of operably control of the solid state switch 32. In this sense, the operation of the solid state switch 32 or switchable element 38, in turn, operates the spark gap device 34.

In the example of FIG. 2, the voltage at the cathode 44 is assumed to be zero volts, the total voltage difference applied by the energy storage element 13 (VT) is divided between, and defined by, the first resistor R1 and the second resistor R2 while the solid state switch 32 is open (and the first pathway is enabled). In this sense, the voltage at the voltage divider output (and the anode 42 of the spark gap device 34) can be calculated as follows:

$${V}_{G} = {V}_{T} ⋆ ( \frac{R 2}{R 1 + R 2} )$$

In the aforementioned calculation, V_{G} is the gap voltage at the anode 42 of the spark gap device 34, VT is the total voltage applied by the energy storage element 13, R1 is the resistance at the first resistor R1, and R2 is the resistance at the second resistor R2. The voltage across the solid state switch can be calculated as follows:

$${V}_{S} = {V}_{T} ⋆ ( \frac{R 1}{R 1 + R 2} )$$

where V_{S} is the voltage at the solid state switch 32. Thus, it is understood that varying, choosing, selecting, adapting, or configuring the impedance at the first and second resistors R1, R2 can be used to vary the ratio of the voltages at different points or nodes of the voltage divider 28, and thus, at the spark gap device 34 and the solid state switch 32.

The controller module 40 within the solid state switch 32 can be tailored to trigger the solid state switch 32 to close in response to the sensing of a predetermined voltage threshold (V_{ST}), as sensed or measured by the voltage sensor 39. Thus, during charging operation (e.g. as the charging power source charges, or rises the application of voltage to the spark gap circuit system 14 over a period of time), the energy storage element 13 voltage (VT) can rise until Vₛ satisfies the predetermined voltage threshold (V_{S}=V_{ST}=V_{TT}*R1/(R1+R2), where V_{TT} is the voltage on the energy storage element 13 at the desired discharge point). Upon satisfaction of the predetermined voltage threshold, the controller module 40, can controllably operate the switchable element 38 to close the switchable element.

In one non-limiting aspect of the disclosure, the first and second resistors R1, R2, the voltage divider 28, or the spark gap circuit system 14 can be configured, selected, or otherwise adapted such that a maximum application of power or voltage by the energy storage element 13, while the switchable element 38 is in the opened position results in a voltage at the voltage divider output (and thus, the anode 42 of the spark gap device 34, V_{G}) that is less than the breakdown voltage of the spark gap device 34. Stated another way, in response to the maximum application of power or voltage by the charging power source 12, the spark gap device 34 will not generate a spark in the gap 46 while the switchable element 38 is in the opened position.

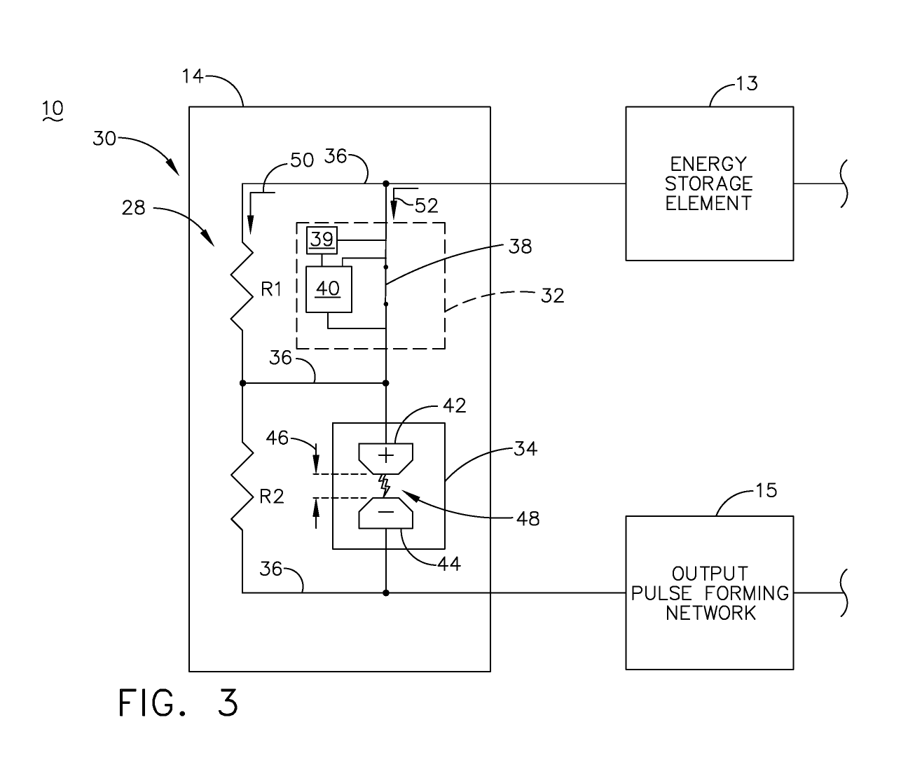

FIG. 3 illustrates the spark ignition system 10 of FIG. 2, wherein the switchable element 38 is in a closed or conducting state. In one non-limiting example, the switchable element 38 can be closed in response to the controller module 40 receiving indication that the voltage V_{S} has risen to satisfy the predetermined voltage threshold, as sensed by the voltage sensor 39. In this sense, the second pathway 52 is enabled. Further, upon closing the switchable element 38, the voltage drop previously experienced by the first resistor is now bypassed, exposing the total voltage applied by the charging power source 12 to the anode 42 of the spark gap device 34, in parallel with the second resistor R2. It is envisioned that the while the total voltage applied to the voltage divider output by the charging power source 12 when the switchable element was open was insufficient to satisfy the breakdown voltage of the spark gap device 34 (e.g. not triggering a spark in the gap 48), the same total voltage applied to anode 42 directly when the switchable element is closed is sufficient to satisfy the breakdown voltage of the spark gap device 34 (e.g. triggering a spark 48 in the gap 46 between the anode 42 and cathode 44, shown schematically). In this example, the closed switchable element 38 becomes a short circuit, where the gap voltage V_{G} becomes the total voltage VT.

The spark gap device 34 breakdown voltage V_{G}BR can be configured to be greater than the maximum voltage spark gap device terminal voltage V_{G}BR, and less than the total voltage V_{TT}. This relationship can be represented as:

V_{GBR}<spark gap device breakdown voltage<V_{TT}

The switch voltage V_{S} can therefore include a range for the switch voltage to trigger the closing of the switchable element 38 between V_{G} and VT. Such a range for switch voltage V_{S} can be about 1 kV, for example. Maintaining the gap voltage V_{G} less than the breakdown voltage prevents the spark gap device 34 from generating a spark until the switchable element 38 closes. Similarly, maintaining the VT above the breakdown voltage further maintains that the spark gap device 34 reliably sparks upon closing of the switch 32. This provides stability for the system to ensure that the spark gap device 34 sparks reliably, even within larger spark gap breakdown voltage threshold range, such as +/−250V.

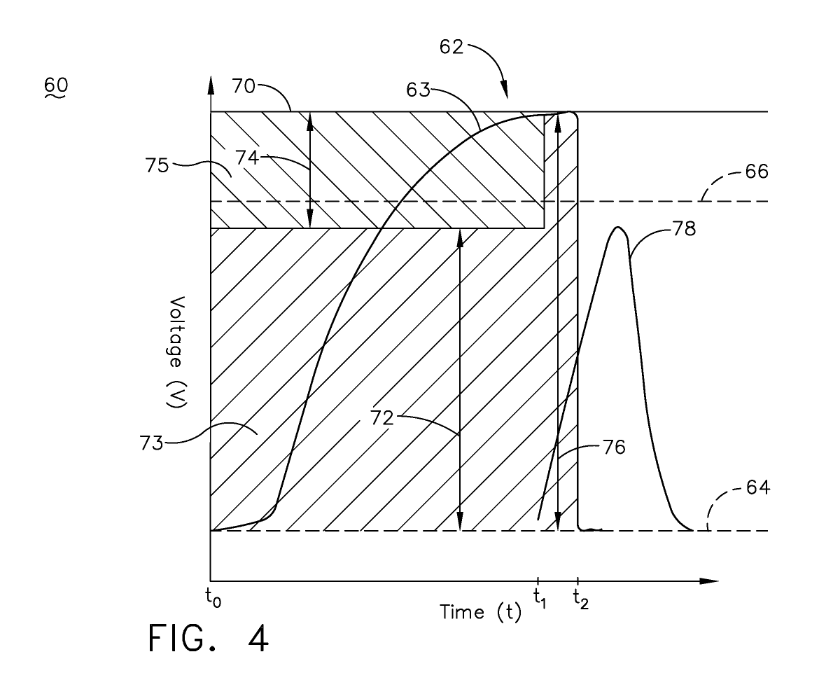

Referring now to FIG. 4, a plot graph 60 includes a voltage plot 62 representing a voltage (V) applied 63 to the spark gap circuit 14 by the charging power source 12 over an example period of time (t). The plot graph 60 further includes a baseline ground voltage 64, a spark gap device breakdown voltage threshold 66, and a maximum total voltage applied 70 by the charging power source 12. A first voltage area 73 can defined an expected voltage range applied to or experienced by the spark gap device 34 (or the second resistor R2) over the charging period of time, while a second voltage area 75 can define an expected voltage range applied to or experienced by the solid state switch 32 (or the first resistor R1) over the charging period of time. During the period of time between t0 and t1, the voltage applied 63 by the charging power source 12 rises to approximately the maximum total voltage 70. During this time, the first voltage area 73 applied to or experience by the spark gap device 34 is V_{G} 72, which is less than the breakdown voltage threshold 66. Likewise, during this time, the second voltage area 75 applied to or experienced by the solid state switch 32 is V_{S} 74. The summation of V_{G} 72 and V_{S} 74 is VT 76, the total voltage.

At time t₁, the voltage applied to the solid state switch 32 (VS 74) can satisfy the predetermined voltage threshold, as sensed by the voltage sensor 39, causing the controller module 40 to operably close the switchable element 38. At this time period between t₁ and t₂, the total voltage VT 76 is applied to the spark gap device 34 by way of the second pathway 52 (bypassing the first resistor R1), while no voltage is dropped by the solid state switch 32 (as it is a short circuit). During this period of time, the voltage applied to the spark gap device 34 (denoted by the first voltage area 73) is greater than the breakdown voltage threshold 66. At time t₂, the spark gap device 34 generates a spark 48, represented by a current plot 78 overlaid upon the voltage plot 62. It should be appreciated that the time (t) is exemplary as shown to facilitate understanding of the concepts described herein. For example, while shown as a space between t₁ and t₂, it may only be nanoseconds, or shorter from between the time when the switchable element 38 closes and the spark 48 is formed across the spark gap device 34. In one non-limiting example, the delay between t₁ and t₂ can be based upon physical or material limitations not germane to the current disclosure.

It should be appreciated that utilizing the solid state switch 32 provides for a significant increase in breakdown gap tolerance for the gap 34, such as by ten times (10x) the tolerance in one non-limiting example. This tolerance is achievable with the circuit as described herein, without the use of radioactive elements, such as Kr85.

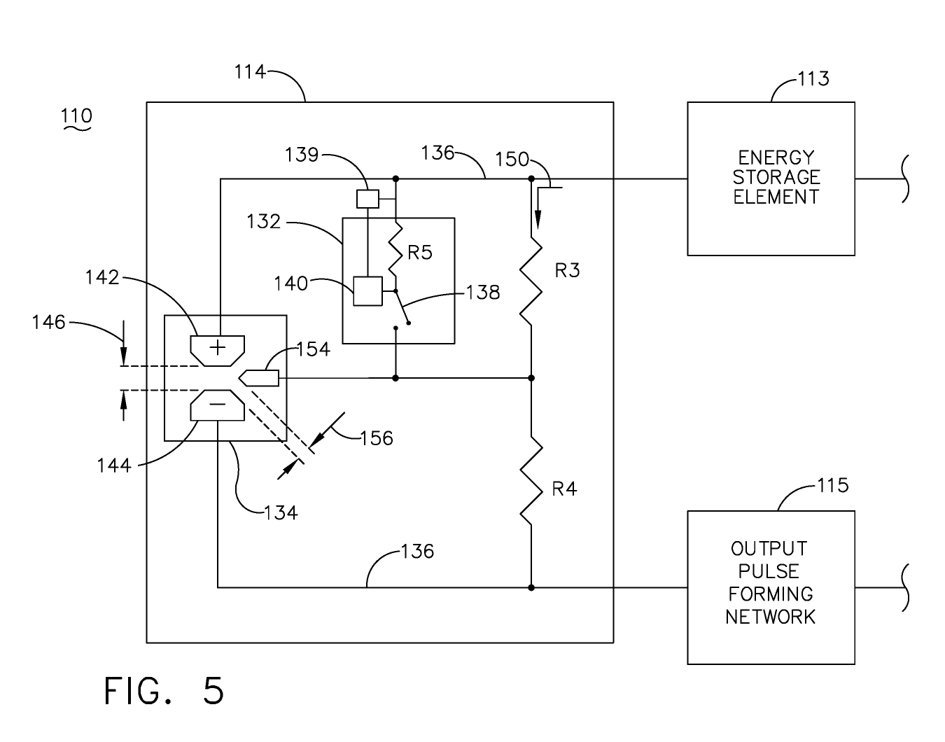

Referring now to FIG. 5, another spark ignition system 110 is illustrated. The spark ignition system 110 can be substantially similar to that of FIGS. 2-3. As such, similar numerals will be used to describe similar elements increased by a value of 100, and discussion will be limited to differences between the two. A difference between the spark ignition system 10 and the spark ignition system 110 is that the spark ignition system 110 can include another spark gap device 134 having a third terminal, or trigger electrode 154.

A spark gap circuit system 114 includes electrical components including a third resistor R3, a fourth resistor R4, and a fifth resistor R5. The third and fourth resistors R3, R4 are arranged along a first pathway 150 to form a voltage divider 128. The fifth resistor R5 is provided within a solid state switch 132, in series with a switchable element 138. Alternatively, the fifth resistor R5 can be positioned exterior of the solid state switch 132. The fifth resistor R5 can be chosen or selected to control the ratio of voltage applied to the solid state switch 132, relative to the third and fourth resistors R3, R4, and a spark gap device 134. The spark gap device 134 is arranged electrically in parallel with the voltage divider 128.

A trigger electrode 154 extends toward a gap 146 between an anode 142 and a cathode 144 for the spark gap device 134. The gap 146 can define a first breakdown voltage, required to generate a spark between the anode 142 and the cathode 144. The trigger 154 can define a trigger gap 156 between the trigger 154 and the cathode 144. The trigger gap 156 can define a second breakdown voltage required to generate a spark between the trigger 154 and the cathode 144. The second breakdown voltage for the trigger gap 156 can be less than that of the first breakdown voltage. In one non-limiting example, the trigger gap 154 can be less than the gap 146 between the anode 142 and the cathode 144. In one example, the trigger gap 156 can be 1.65 mm or 0.065 in. The distance between the trigger 154 and the anode 142 can be 2.80 mm or 0.110 in, being greater than that of the trigger gap 156. As a breakdown voltage for the spark gap device 134 is proportional to the distance between elements, and the trigger gap 156 is less than the gap 146 and the distance between the trigger 154 and the anode 142, the breakdown voltage is smallest for the trigger gap 156 (i.e. the trigger gap breakdown voltage). In one example, the breakdown voltage for the trigger gap can be about 3.05 kV, the breakdown voltage for the distance between the trigger 154 and the anode 142 can be about 4.75 kV, and the breakdown voltage for the gap 146 can be about 7.8 kV. Therefore, it should be appreciated that a lesser voltage is required to form a spark across the trigger gap 156, compared with the gap between the trigger electrode 154 and the anode 142, and compared with the gap 146 between the anode 142 and cathode 144.

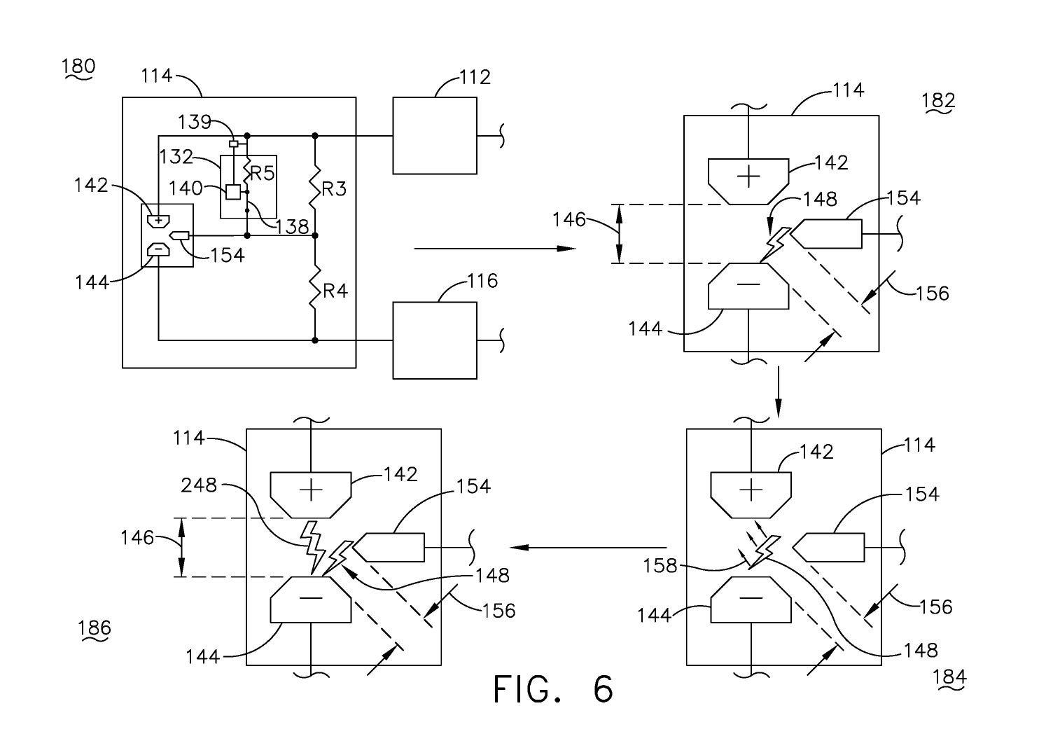

Referring now to FIG. 6, a flow chart illustrates the operation of the spark gap device 134 utilizing the trigger 154 with the shortened trigger gap 156. The flow chart is separated into a first stage 180, a second stage 182, a third stage 184, and a fourth stage 186. At the first stage 180, the voltage across the solid state switch 132 increases until the controller module 140 controllably closes the switchable element 138 in response to the voltage sensor 139 sensing or measuring a voltage satisfying a predetermined threshold voltage. Such a voltage can be about 2.5 kV, for example, which is less than the breakdown voltage across the trigger gap 156. When the switchable element 138 closes, the solid state switch 132 conducts current (limited by the fifth resistor R5), bypassing the third resistor R3. The voltage at the voltage divider output (connected with the trigger electrode 154) at this time can be greater than the trigger gap breakdown voltage, while the total voltage applied between the anode 142 and cathode 144 is still less than the spark gap device 134 breakdown voltage. Thus, at the second stage 182, the application of voltage at the voltage divider output greater than the trigger gap breakdown voltage, generates a first spark, arc, or glow discharge 148 between the trigger electrode 154 and the cathode 144.

As shown in the third stage 184, the first discharge 148 across the trigger gap 156 releases free electrons, photons 158, or a combination thereof, and ionizes the space, air, or gases in the trigger gap 156. The ionized trigger gap stimulates ionization in the anode 142 and cathode 144 gap. The anode 142 further attracts the free electrons. At stage 186, the free electrons pass into the gap 146, effectively reducing the threshold breakdown voltage across the gap 146 to a breakdown voltage threshold value less than the total voltage applied to the anode 142 and cathode 144, and causing a second spark 248 to be generated between the anode 142 and the cathode 144. The spark 248 then forms a short circuit across the spark gap device 134, which can be provided to the igniter 16. Therefore, the aforementioned spark gap device 134 can operate by generating a first discharge 148 by way of the trigger electrode 154, which in turn generates the second spark 248 across the spark gap device 134, without expressly generating a voltage greater than the designed breakdown voltage between the anode 142 and cathode 144, but rather by lowering the effective breakdown voltage between the anode 142 and cathode 144 due to the introduction of ionized gases and free electrons from the first trigger discharge 148. Thus, the second spark 248 can be generated without modification of the total voltage applied to the anode 142 and cathode 144 by the energy storage element 113. The arrangement of the spark gap circuit system 114 further minimizing the current across the solid state switch 132.

In one example, the main gap breakdown voltage between the anode 142 and the cathode 144 should be just above the overall target breakdown voltage. This can provide for a fail-safe operation to discharge 148 between the anode 142 and cathode 144 in the event of failure of the solid state switch 132. Furthermore, the trigger gap 156 to the cathode 144 should be positioned such that the anode 142 is in direct electrical line of sight to aid in the breakdown of the gap 146 between the anode 142 and the cathode 144. Further still, the distance between the anode 142 and the cathode 144 should be less than the total of the distance between the trigger 154 and the cathode 144 added to the distance between the trigger 154 and the anode 142. This causes further discharges to migrate away from the trigger 154, which can reduce overall wear to the trigger 154.

It should be appreciated that the circuits as described herein provide for gap breakdown voltages that have a much wider tolerance, such as about a 1 kV window, supporting the use of non-radioactive elements. As such, the electrode work functions are not as critical, and metal on the anode and cathode can be replaced with good wear metals. Similarly, gas breakdown within the spark gap device 34, 134 is not as critical. Elements such as a gas mixtures can be replaced with only N₂.

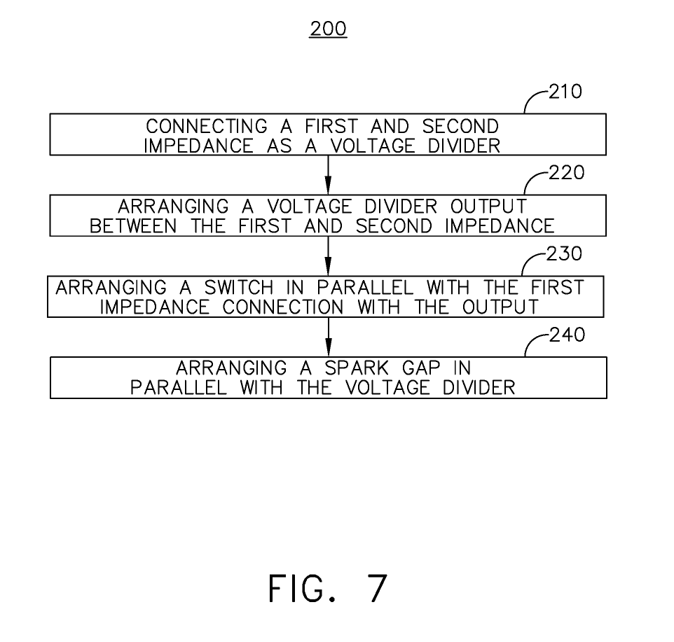

Referring now to FIG. 7, a method 200 for providing a spark gap circuit can include: at 210, connecting a first impedance and a second impedance in series for a voltage divider; at 220, arranging a voltage divider output between the first and second impedance; at 230, arranging a switch in parallel with the first impedance and connected with the voltage divider output; and, at 240, arranging a spark gap device defining a breakdown voltage electrically in parallel with at least a portion of the voltage divider. The values for the first and second impedance can be fixed such that, in response to the circuit receiving a predetermined voltage supply greater than the breakdown voltage, the spark gap device does not generate a spark when the switchable element is in an open state, and the spark gap device does generate a spark when the switchable element is in a closed state.

The sequence depicted is for illustrative purposes only and is not meant to limit the method 200 in any way as it is understood that the portions of the method can proceed in a different logical order, additional or intervening portions can be included, or described portions of the method can be divided into multiple portions, or described portions of the method can be omitted without detracting from the described method. For example, in one non-limiting aspect of the disclosure, the spark gap device 34, 134 is arranged electrically in parallel with the second impedance R2, R4 and connected with the voltage divider output, and wherein selecting further includes selecting the values for the first impedance R1, R3 and the second impedance R2, R4 such that a potential difference applied to the spark gap device 34, 134 is less than the breakdown voltage when the switchable element 38, 138 is in the open state, and wherein the potential difference applied to the spark gap device 34, 134 is greater than the breakdown voltage when the switchable element 38, 138 is in the closed state. In another non-limiting aspect of the disclosure, the spark gap device 34, 134 is arranged electrically in parallel with the voltage divider portion of the spark gap circuit system 14, 114, and wherein selecting further includes selecting the values for the first impedance R1, R3 and the second impedance R2, R4 such that a preliminary spark in the spark gap device 34, 134 is triggered between a trigger electrode 154 and a spaced cathode 144 electrode in response to the switchable element 138 actuating from the open state to the closed state, the trigger electrode 154 connected with the voltage divider output, and such that the preliminary discharge 148 triggers a primary spark 248 between the cathode electrode 144 and a spaced anode electrode 142.

To the extent not already described, the different features and structures of the various aspects can be used in combination, or in substitution with each other as desired. That one feature is not illustrated in all of the aspects is not meant to be construed that it cannot be so illustrated, but is done for brevity of description. Thus, the various features of the different aspects can be mixed and matched as desired to form new aspects, whether or not the new aspects are expressly described. All combinations or permutations of features described herein are covered by this disclosure.

This written description uses examples to disclose aspects of the disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A circuit comprising:
a voltage divider having a first impedance and a second impedance in series, with a voltage divider output between the first and second impedances;
a switchable element arranged electrically in parallel with the first impedance and connected with the voltage divider output, and having an open state enabling a first current path through the first impedance and a closed state enabling a second current path bypassing the first impedance; and
a spark gap device arranged electrically in parallel with at least a portion of the voltage divider and defining a breakdown voltage whereby the spark gap device generates a spark in response to application of voltage greater than the breakdown voltage;
wherein, the first impedance and the second impedance are selected such that, in response to the circuit receiving a voltage supply greater than the breakdown voltage, the spark gap device does not generate the spark when the switchable element is in the open state and the spark gap device generates the spark when the switchable element is in the closed state and bypasses the first impedance.

2. The circuit of claim 1 wherein the spark gap device includes two spaced electrodes enclosed in a fluidly sealed housing.

3. The circuit of claim 2 wherein the spark gap device includes a gas within the housing.

4. The circuit of claim 3 wherein the gas is non-radioactive.

5. The circuit of claim 1 wherein the spark gap device is arranged electrically in parallel with the second impedance and connected with the voltage divider output.

6. The circuit of claim 5 wherein, in response to the circuit receiving a voltage supply greater than the breakdown voltage and in response to the switchable element in the open state, the potential difference applied to the spark gap device is less than the breakdown voltage.

7. The circuit of claim 6 wherein, in response to the circuit receiving a voltage supply greater than the breakdown voltage and in response to the switchable element in the closed state, the potential difference applied to the spark gap device is greater than the breakdown voltage.

8. The circuit of claim 7 wherein the spark gap device defines a breakdown voltage range.

9. The circuit of claim 8 wherein, in response to the circuit receiving a voltage supply greater than the breakdown voltage and in response to the switchable element in the closed state, the potential difference applied to the spark gap device is greater than the breakdown voltage range.

10. The circuit of claim 1 wherein the switchable element includes a voltage sensor.

11. The circuit of claim 10, further comprising a switch controller module communicatively connected with the voltage sensor and the switchable element, and configured to actuate the switchable element from the opened state to closed state in response comparing the voltage sensed by the voltage sensor with a switchable element voltage threshold value.

12. The circuit of claim 1 wherein the spark gap device is arranged electrically in parallel with the voltage divider.

13. The circuit of claim 12 wherein the spark gap device includes an anode electrode connected with a power input, a cathode electrode spaced from the anode electrode and connected with a power output, and a trigger electrode spaced from the anode electrode and the cathode electrode and connected with the voltage divider output.

14. The circuit of claim 13 wherein the spark gap device defines a first breakdown voltage between the anode electrode and the cathode and a second breakdown voltage between the trigger electrode and the cathode, wherein the second breakdown voltage is less than the first breakdown voltage.

15. The circuit of claim 14 wherein, in response to the circuit receiving a voltage supply between the power input and the power output, the voltage supply greater than the second breakdown voltage and less than the first breakdown voltage, and in response to the switchable element in the opened state, the potential difference applied between the trigger electrode and the cathode electrode is less than the second breakdown voltage.

16. The circuit of claim 15 wherein, in response to the circuit receiving the voltage supply greater than the second breakdown voltage and less than the first breakdown voltage, and in response to the switchable element in the closed state, the potential difference applied between the trigger electrode and the cathode electrode is greater than the second breakdown voltage, generating the spark between the trigger electrode and the cathode electrode.

17. The circuit of claim 16 wherein, the spark gap device is adapted such that the spark generated between the trigger electrode and the cathode electrode reduces the effective first breakdown voltage between the anode electrode and the cathode electrode to less than the voltage supply received by the circuit, generating a spark between the anode electrode and the cathode electrode.

18. A method of providing a spark gap circuit, the method comprising:
connecting a first impedance and a second impedance in series for a voltage divider;
arranging a voltage divider output between the first and second impedance;
arranging a switchable element electrically in parallel with the first impedance and connected with the voltage divider output;
arranging a spark gap device defining a breakdown voltage electrically in parallel with at least a portion of the voltage divider; and
selecting values for the first impedance and the second impedance such that, in response to the circuit receiving a predetermined voltage supply greater than the breakdown voltage, the spark gap device does not generate a spark when the switchable element is in an open state and the spark gap device generates a spark when the switchable element is in a closed state.

19. The method of claim 18 wherein the spark gap device is arranged electrically in parallel with the second impedance and connected with the voltage divider output, and wherein selecting further includes selecting the values for the first impedance and the second impedance such that a potential difference applied to the spark gap device is less than the breakdown voltage when the switchable element is in the open state, and wherein the potential difference applied to the spark gap device is greater than the breakdown voltage when the switchable element is in the closed state.

20. The method of claim 18 wherein the spark gap device is arranged electrically in parallel with the voltage divider portion of the spark gap circuit, and wherein selecting further includes selecting the values for the first impedance and the second impedance such that a preliminary spark in the spark gap device is triggered between a trigger electrode and a spaced cathode electrode in response to the switchable element actuating from the open state to the closed state, the trigger electrode connected with the voltage divider output, and such that the preliminary spark triggers a primary spark between the cathode electrode and a spaced anode electrode.
